(19) United States
(12) Patent Application Publication
(10) Pub. No.: US 2026/0231497 A1
(43) Pub. Date: Aug. 6, 2026

(54) PEALD IN-SITU DOPED SION FOR GAA STRUCTURE DEVICE PERFORMANCE AND YIELD

(71) Applicant: Taiwan Semiconductor Manufacturing Co., Ltd., Hsinchu (TW)

(72) Inventors: Cheng-I LIN, Hsinchu (TW); Cheng-Yu WEI, Hsinchu (TW); Shu-Han CHEN, Hsinchu (TW); Chi On CHUI, Hsinchu (TW)

(73) Assignee: Taiwan Semiconductor Manufacturing Co., Ltd., Hsinchu (TW)

(21) Appl. No.: 19/042,970

(22) Filed: Jan. 31, 2025

(51) Int. Cl. H10D 64/01; H01L 21/02; H10D 30/00; H10D 30/01; H10D 30/43; H10D 30/67; H10D 62/10; H10D 84/03; H10D 84/83

(52) U.S. Cl. CPC H10D 64/017; H10D 30/014; H10D 30/019; H10D 30/43; H10D 30/502; H10D 30/6735; H10D 62/121; H10D 64/021; H10D 84/038; H10D 84/832; H10P 14/6336

(57) ABSTRACT

A fin structure is formed over a substrate. An insulation feature is formed over the substrate and laterally with respect to the fin structure. A dielectric layer of SiON is formed over the insulation feature and over the fin structure. A dummy gate structure is formed over the insulation feature, and the dielectric layer separates the dummy gate structure from the insulation feature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Recently, multi-gate transistors have been introduced in an effort to improve gate control by increasing gate channel coupling, reduce OFF-state current, and reduce short-channel effects (SCEs). One such multi-gate transistor is the gate-all-around (GAA) transistor. In some examples, a gate structure of a GAA transistor wraps around a channel region providing access to the channel on multiple sides. GAA transistors are compatible with complementary metal-oxide-semiconductor (CMOS) processes and their structure allows them to be aggressively scaled while maintaining gate control and mitigating SCEs. The channel region of an GAA transistor is formed from stacked channel structures, such as nanowires, nanosheets, other nanostructures, and/or other appreciable variations. As the semiconductor industry further progresses into sub-10 nanometer (nm) technology process nodes in pursuit of higher device density, higher performance, and lower costs, integration of fabricating the GAA features around stacked nanosheets can be challenging. For example, conventionally in a GAA process flow, a gate structure extending around the bottommost channel structure also engages a top surface of the semiconductor substrate thereunder, causing strong leakage current under the stacked channel structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example fabrication process in accordance with some implementations.

FIGS. 2A-2M-1 illustrate a semiconductor structure in various stages of an example fabrication process in accordance with some implementations.

### DETAILED DESCRIPTION

The following disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features are formed in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor fabrication of multi-gate transistors in a semiconductor device. As used herein, a semiconductor device refers to for example, one or more transistors, integrated circuits, a semiconductor chip (e.g., memory chip, logic chip on a semiconductor die), a stack of semiconductor chips, a semiconductor package, a semiconductor wafer, and the like. The term “multi-gate transistor” refers to a transistor, such as a field effect transistor (FET) that has gate material(s) disposed on multiple sides of a channel structure of the transistor. In some examples, the multi-gate transistor is referred to as a gate-all around (GAA) transistor when gate material(s) are disposed on at least four sides of a channel structure of the multi-gate transistor. The term “channel structure” is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. In some examples, the channel structure is referred to as a “nanowire,” a “nanosheet,” and the like that as used herein includes channel structures of various geometries (e.g., cylindrical, bar-shaped) and various dimensions. In a device of such multi-gate transistors, an insulation structure, e.g., a shallow trench insulation feature, is positioned to separate transistors or regions of transistors. The present disclosure provides a protective mask layer between a shallow trench insulation structure and a gate structure formed over the shallow trench insulation structure so that the shallow trench insulation structure will maintain its integrity in fabrication procedures performed following the formation of the shallow trench insulation structure to reduce electrical leakage of the gate structure formed on the shallow trench insulation structure. The protective mask layer is doped in-situ to introduce a percentage of nitrogen ions into a dielectric material using an PEALD procedure. Tuning of one or more of the mixed gas ratio among Ar, O₂, and N₂, different kind of noble gas selected from He, Ne, Ar, or Kr, the process temperature, or the PEALD power helps insertion of demanded percentage of nitrogen ions impurity into the dielectric material and densify the dielectric material. As such the dielectric material of the protection mask layer includes etch selectivity with respect to silicon oxide, which retards the etch rate of the protection hard mask layer in an oxide removal process to prevent STI damage. Consequently, the risk of epitaxial damage or metal gate extrusion can be reduced by the protection hard mask layer, no matter whether a semiconductor interposer or a dielectric interposer is used in the relevant GAA fabrication scheme.

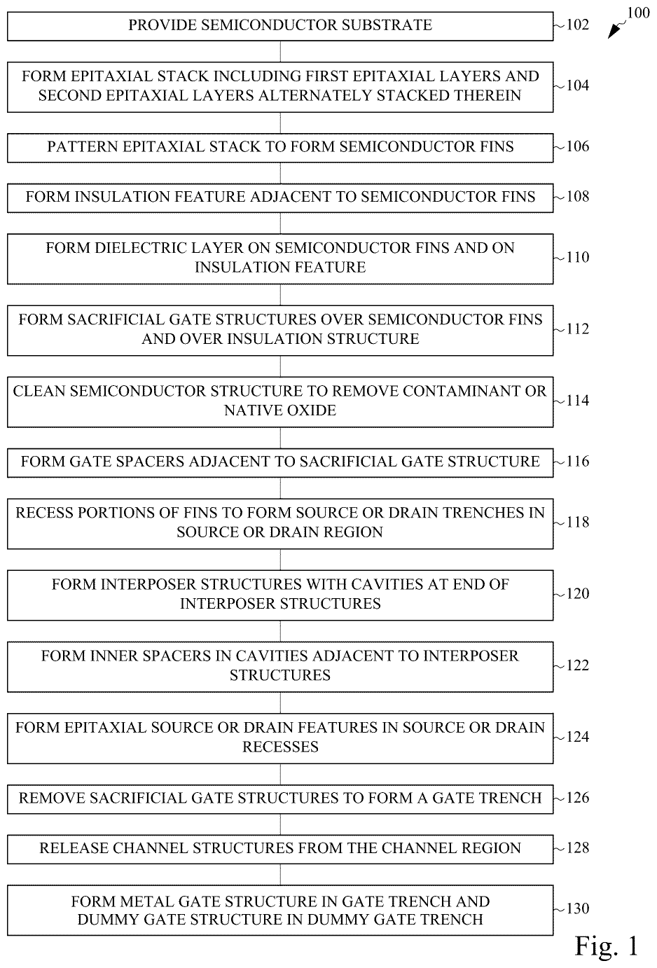

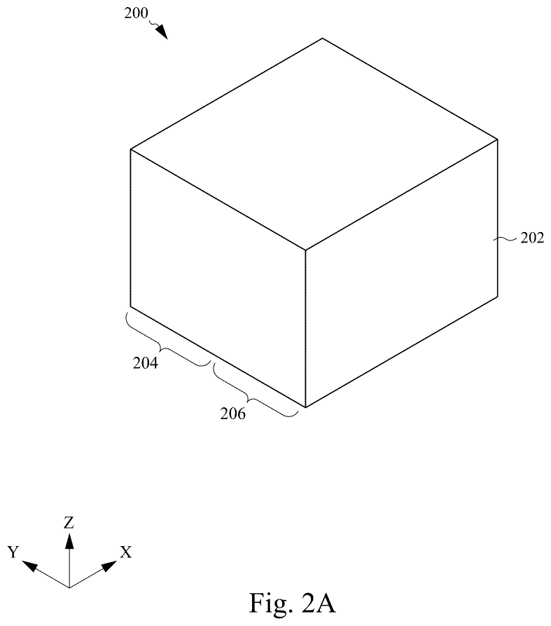

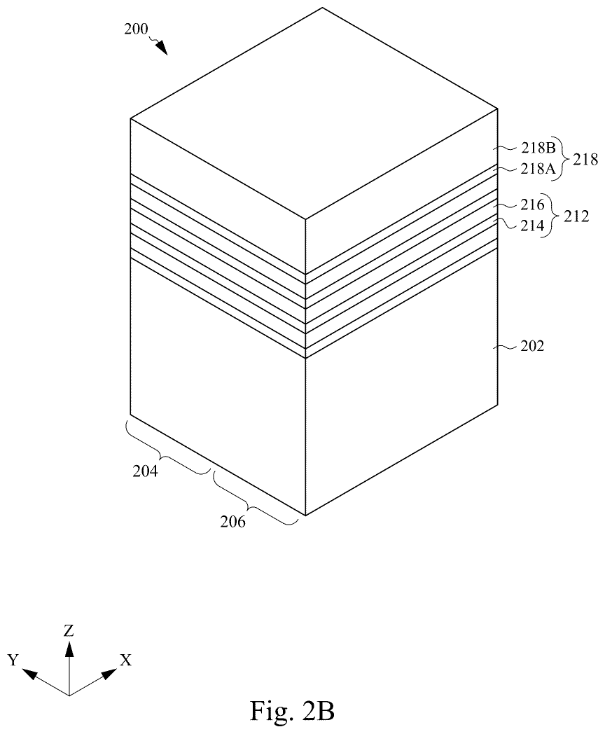

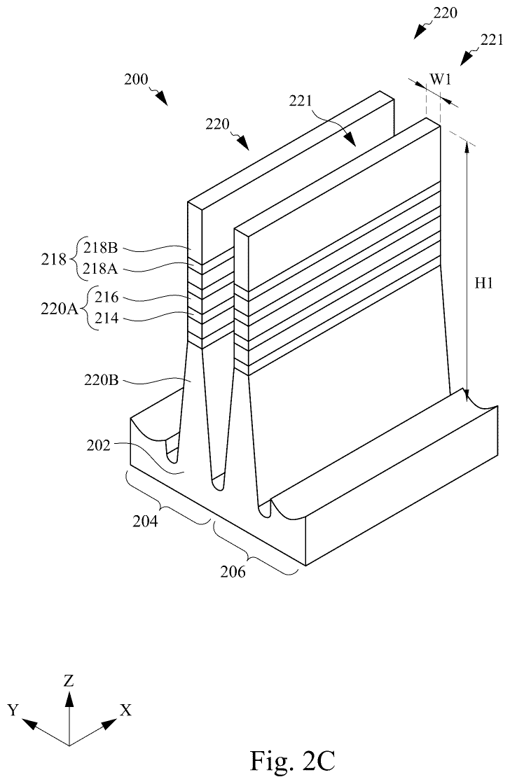

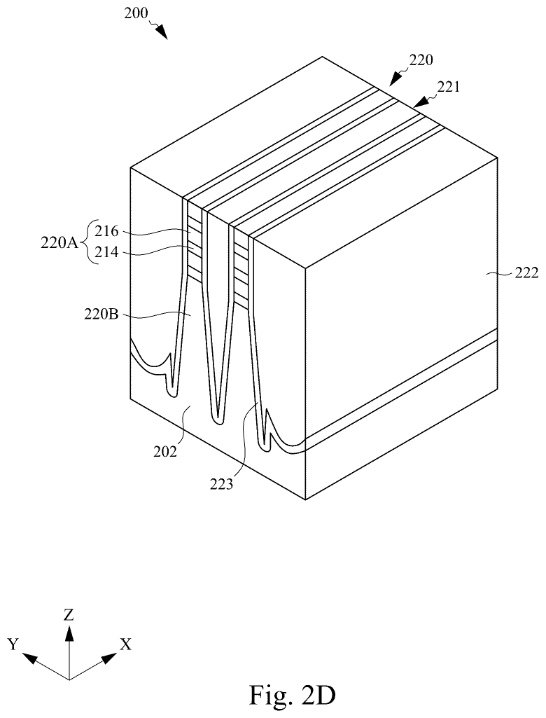

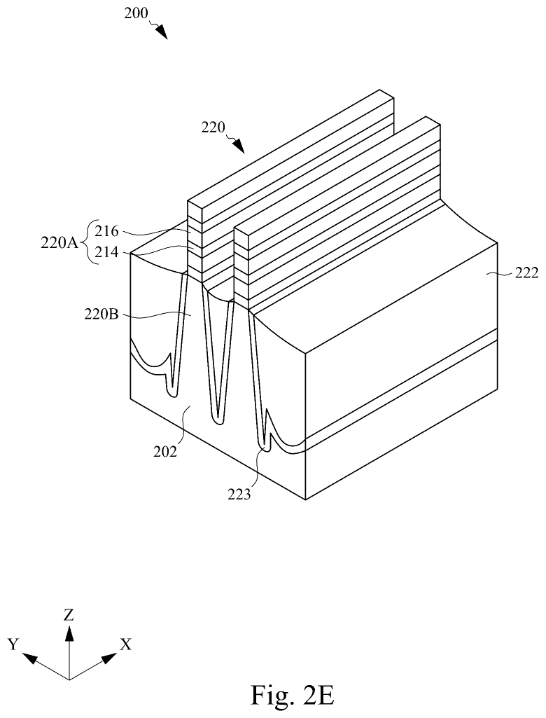

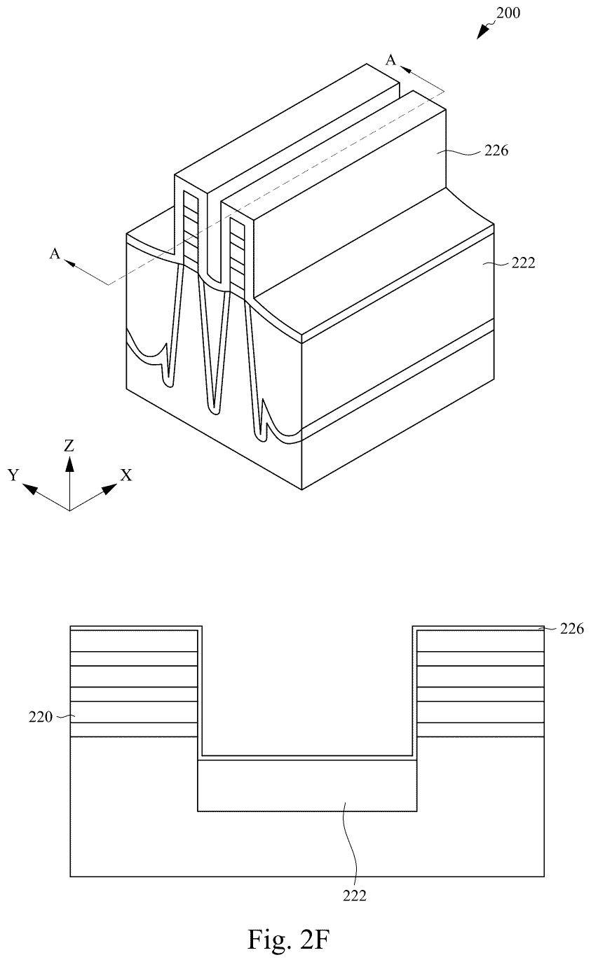

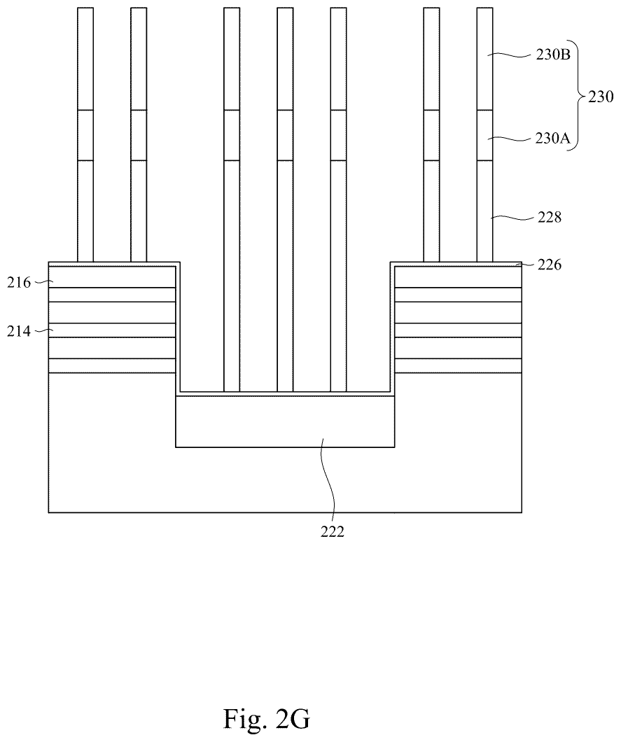

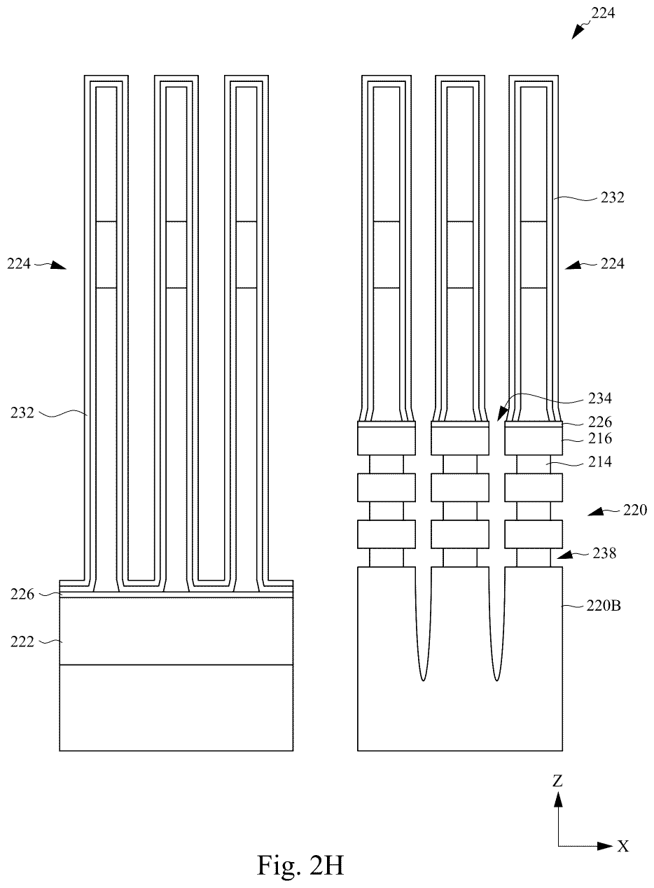

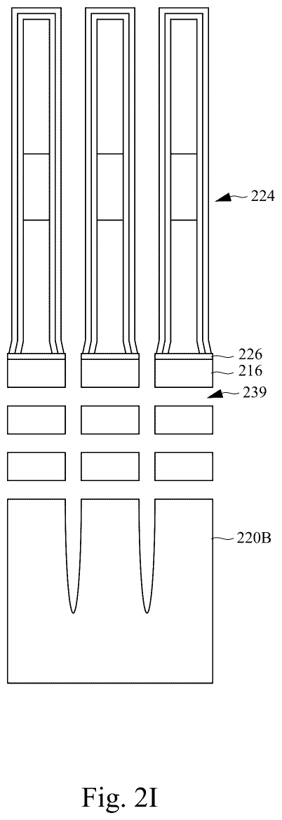

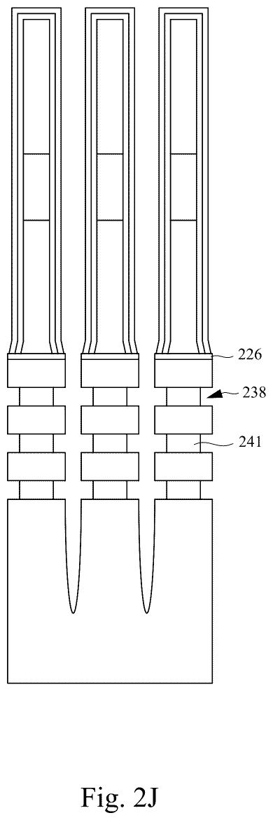

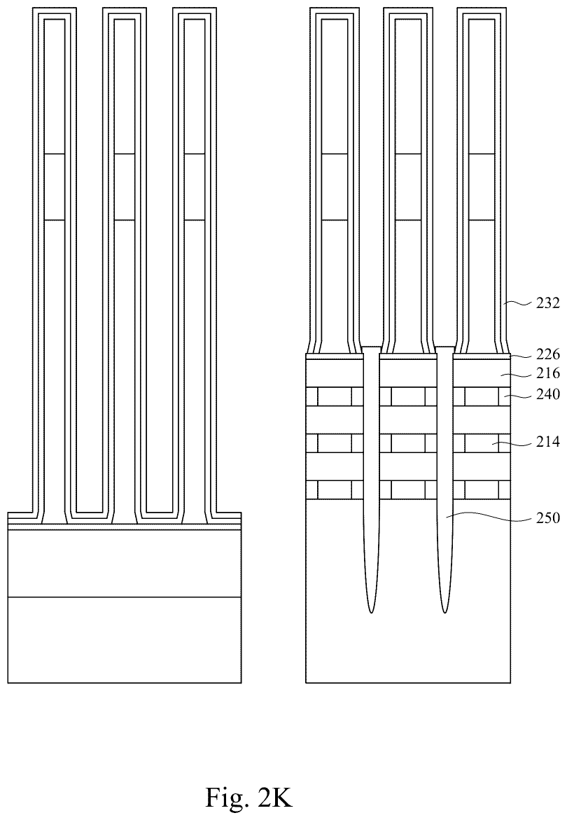

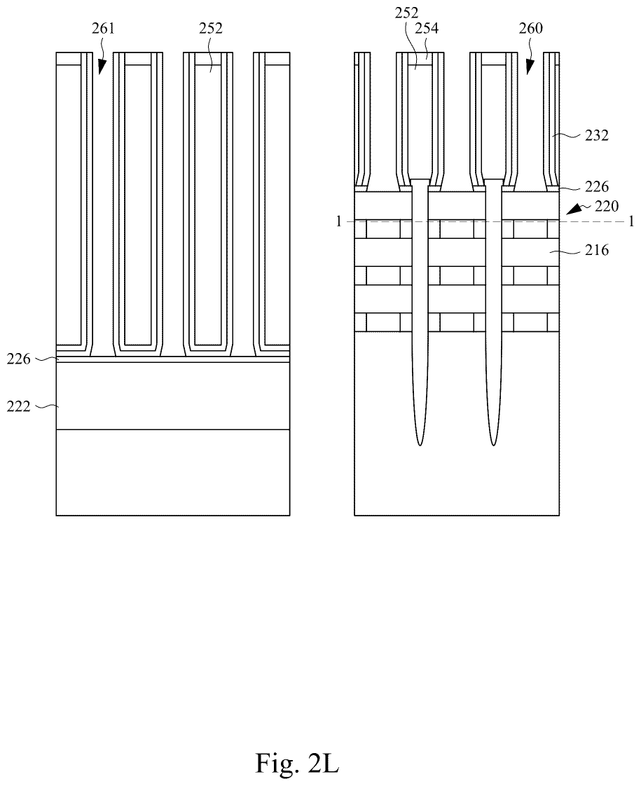

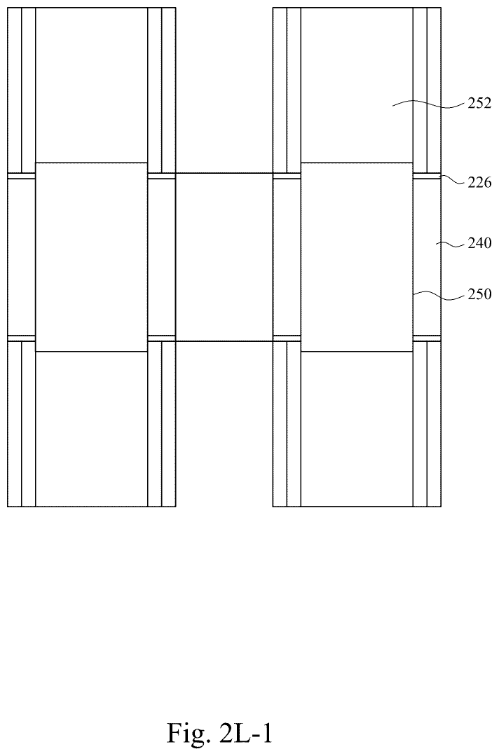

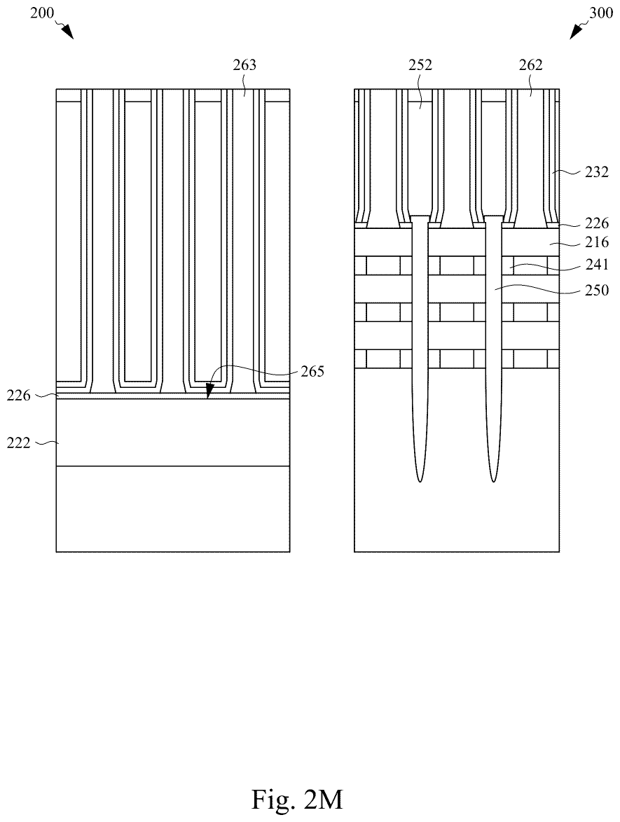

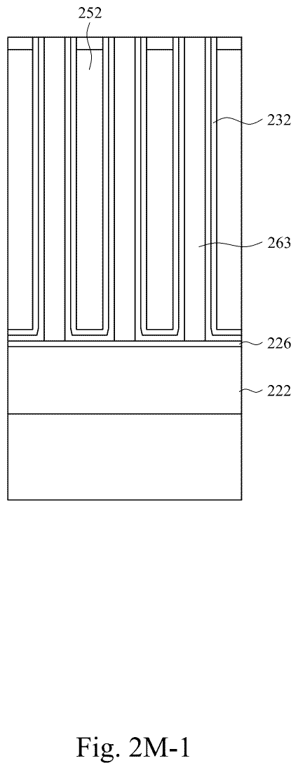

FIG. 1 shows an example process 100 of making a semiconductor structure. FIGS. 2A-2M show a semiconductor structure 200 at various stages of fabrication according to the process 100. The process 100 is merely an example, and is not intended to limit the present disclosure. Additional steps can be provided before, during, and after those explicitly described the example process 100, and some of the operations described can be moved, replaced, or eliminated for additional or alternative implementations of the process 100. Additional features can be added in the semiconductor device depicted in FIGS. 2-25B and some of the features described below can be replaced, modified, or eliminated in other implementations of the semiconductor device.

As with the semiconductor fabrication process implementations and example structures discussed herein, it is understood that parts of the semiconductor device 200 may be fabricated by a CMOS technology process flow, and thus some processes are only briefly described herein. Further, the example semiconductor devices or structures may include various other devices and features, such as other types of devices, e.g., additional transistors, bipolar junction transistors, resistors, capacitors, inductors, diodes, fuses, static random access memory (SRAM) and/or other logic circuits, etc., but is simplified for a better understanding of the implementations of the present disclosure. In some implementations, the example devices include a plurality of semiconductor devices (e.g., transistors), including p-type FETs, n-type FETs, etc., which may be interconnected. Moreover, it is noted that the process steps of method 100, including any descriptions given with reference to FIGS. 2A-2M, are merely examples and are not intended to be limiting

Referring to FIG. 1, in operation 102, with reference also to FIG. 2A, a semiconductor substrate 202 (also referred to as the substrate 202) is provided. In some implementations, the substrate 202 may be a semiconductor substrate such as a silicon (Si) substrate. In some implementations, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various doping configurations depending on design requirements as is known in the art. For example, in the illustrated implementation, the substrate 202 is separated into regions 204 and 206. As to be explained in greater detail below, two or more transistors are formed in and/or over the regions 204 and 206 of the substrate 202. In some implementations, an n-type FET (NFET) and a p-type FET (PFET) will be formed in and/or over the regions 204 and 206, respectively. Thus, the region 204 is also referred to as the NFET region 204 and the region 206 is also referred to as the PFET region 206 in the present disclosure. The regions 204 and 206 may include various doping configurations depending on design requirements as is known in the art. For example, different doping profiles (e.g., a p-well in the region 204 and an n-well in the region 206) may be formed in the respective regions designed for different device types (e.g., NFETs or PFETs). The suitable doping may include ion implantation of dopants and/or diffusion processes, such as boron (B) for forming a p-well in the region 204 and phosphorous (P) for forming an n-well in the region 206.

In operation 104, with reference also to FIG. 2B, one or more semiconductor layers, e.g., epitaxial semiconductor layers, are formed over the substrate 202. In some implementations, an epitaxial stack 212 is formed over the regions 204 and 206. The epitaxial stack 212 includes epitaxial layers 214 of a first composition interposed by epitaxial layers 216 of a second composition. The epitaxial layers 214 and the epitaxial layers 216 are alternately stacked in the epitaxial stack 212. The first and second composition of the layers 214, 216 can be different. In an illustrative example, the epitaxial layers 214 are silicon germanium SiGe and the epitaxial layers 216 are silicon Si. For example, the epitaxial stack 212 includes SiGe layers 214 and Si layers 216 arranged in an alternating manner. However, other implementations are possible including those that provide for a first composition and a second composition having different oxidation rates and/or etch selectivity. For example, the silicon oxidation rate is less than the SiGe oxidation rate. It is noted that three (3) layers of each of the epitaxial layers 214 and 216 are illustrated in FIG. 2B, which is for illustrative purposes only and not intended to be limiting the scope of the disclosure. It can be appreciated that any number of epitaxial layers can be formed in the epitaxial stack 212 and the number of layers can be designed or configured based on the number of channel structures for the device 200. In some implementations, the number of each of epitaxial layers 216 or epitaxial layers 214 is between 2 and 10, such as 4 or 5. Further, in some implementations, the number of the epitaxial layers 214 and the number of the epitaxial layers 216 may not be the same as one another.

In some implementations, the epitaxial layer 214 has a thickness ranging from about 4 nm to about 12 nm. The epitaxial layers 214 of the stack are substantially uniform in thickness. In some implementations, the epitaxial layer 216 has a thickness ranging from about 3 nm to about 6 nm. In some implementations, the epitaxial layers 216 of the stack are substantially uniform in thickness. In some implementations, for a first type of device, e.g., n-type device, the epitaxial layer 216 of Si may serve as channel region(s) for a subsequently-formed multi-gate device and its thickness is chosen based on device performance considerations. The epitaxial layer 214 of SiGe may serve to reserve a spacing (or referred to as a gap) between adjacent channel region(s) for a subsequently-formed multi-gate device and its thickness is chosen based on device performance considerations. As such, the epitaxial layer 214 of SiGe may be formed to be an interposer structure or may be replaced by a dielectric interposer structure as further discussed herein. For a second type of device, e.g., p-type device, the epitaxial layer 214 of SiGe may serve as channel region(s) for a subsequently-formed multi-gate device and its thickness is chosen based on device performance considerations, and the epitaxial layer 216 of Si may serve to reserve a spacing (or referred to as a gap) between adjacent channel region(s) for a subsequently-formed multi-gate device and its thickness is chosen based on device performance considerations. For the n-type of devices, as an illustrative example used herein, the epitaxial layer 214 is also referred to the sacrificial layer 214 and the epitaxial layer 216 is also referred to as the channel layer 216 or the channel structure 216.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some implementations, the epitaxially grown layers, such as the layers 216, include the same material as the substrate 202, such as silicon (Si). In some implementations, the epitaxially grown layers 214 and 216 include a different material than the substrate 202. As stated above, in at least some examples, the epitaxial layer 214 includes an epitaxially grown Si1-xGex layer (e.g., x is about 25~55%) and the epitaxial layer 216 includes an epitaxially grown Si layer. Alternatively, in some implementations, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation and etch selectivity properties. In various implementations, the epitaxial layers 214 and 216 are substantially dopant-free (i.e., having an extrinsic dopant concentration from about 0 cm⁻³ to about 1×1017 cm⁻³), where for example, no intentional doping is performed during the epitaxial growth process.

In some implementations, a mask layer 218 is formed over the epitaxial stack 212. In some implementations, the mask layer 218 includes a first mask layer 218A and a second mask layer 218B. The first mask layer 218A is a pad oxide layer made of silicon oxide, which can be formed by a thermal oxidation process. The second mask layer 218B is made of silicon nitride (SiN), which is formed by chemical vapor deposition (CVD), including low pressure CVD (LPCVD) and plasma enhanced CVD (PECVD), physical vapor deposition (PVD), atomic layer deposition (ALD), or other suitable process.

In operation 106, with reference also to FIG. 2C, the epitaxial stack 212 is patterned to form semiconductor fin structures 220 (also referred to as fins 220). In various implementations, each of the fins 220 includes an upper portion 220A (also termed as epitaxial portion 220A) of the interleaved epitaxial layers 214 and 216 and a bottom portion 220B that is formed by patterning a top portion of the substrate 202. The bottom portion 220B still has a fin shape protruding from the substrate 202 and is also termed as the fin-shape base 220B. The mask layer 218 is patterned into a mask pattern by using patterning operations including photo-lithography and etching. In some implementations, operation 106 patterns the epitaxial stack 212 using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one implementation, a material layer is formed over a substrate and patterned using a photolithography process. Spacers are formed alongside the patterned material layer using a self-aligned process. The material layer is then removed, and the remaining spacers, or mandrels, may then be used to pattern the epitaxial stack 212 in an etching process, such as a dry etch (e.g., reactive ion etching), a wet etch, and/or other suitable process, through openings defined in the patterned mask layer 218. The stacked epitaxial layers 214 and 216 are thereby patterned into fins 220 with trenches 221 between adjacent fins. Each of the fins 220 protrudes upwardly in the z-direction from the substrate 202 and extends lengthwise in the x-direction. In FIG. 2C, two (2) fins 220 are spaced apart along the y-direction with one fin disposed above the NFET region 204 and one fin disposed above the PFET region 206. But the number of the fins is not limited to two, and may be as small as one or more than two. In some implementations, one or more dummy fin structures are formed on both sides of the fins 30 to improve pattern fidelity in the patterning operations. The width W1 of the upper portion of the fins 220 along the y-direction is in a range from about 10 nm to about 40 nm in some implementations, or in a range from about 20 nm to about 30 nm in other implementations. The height H1 along the Z direction of the fins 220 is in a range from about 100 nm to about 200 nm in some implementations.

In operation 108, with reference also to FIG. 2D, the trenches 221 between adjacent semiconductor fins 220 are filled with one or more dielectric materials to form an insulation feature 222 that adjacent to semiconductor fins 220. The insulation feature 222 may include one or more dielectric layers. Suitable dielectric materials for the insulation feature 222 may include silicon oxides, silicon nitrides, silicon carbides, fluorosilicate glass (FSG), low-K dielectric materials, and/or other suitable dielectric materials. The dielectric material may be deposited by any suitable technique including thermal growth, CVD, HDP-CVD, PVD, ALD, and/or spin-on techniques. Then, a planarization operation, such as a chemical mechanical polishing (CMP) method, is performed such that the upper surface of the topmost second semiconductor layer 216 (or first semiconductor layer 214) is exposed from the insulating feature 222. Operation 108 subsequently recesses the insulation features 222 to form shallow trench isolation (STI) features (also denoted as STI features 222), as shown in FIG. 2E. Any suitable etching technique may be used to recess the insulation features 222 including dry etching, wet etching, RIE, and/or other etching methods, and in an example implementation, an anisotropic dry etching is used to selectively remove the dielectric material of the insulation features 222 without etching the fins 220. In some implementations, the mask layer 218 is removed by a CMP process performed prior to the recessing of the insulation features 222. In some implementations, the mask layer 218 is removed by an etchant used to recess the insulation features 222. In the illustrated implementation, the STI feature 222 is disposed on sidewalls of the fin-shape base 220B. A top surface of the STI feature 222 may be coplanar with a bottom surface of the epitaxial portion 220A (or a top surface of the fin-shape base 220B) or below the bottom surface of the epitaxial portion 220A (or the top surface of the fin-shape base 220B) for about 1 nm to about 10 nm. In some implementations, a liner layer 223 is blanket deposited over the fins 220 before depositing the insulation feature 222, as shown FIG. 2D. In some implementations, the liner layer 223 is made of SiN or a silicon nitride-based material (e.g., SiON, SiCN or SiOCN). Then, as shown in FIG. 2E, liner layer 223 is recessed so that the epitaxial portion 220A of the fins 220 are exposed.

In operation 110, with reference also to FIG. 2F, a blanket layer of dielectric material 226 is formed on the fins 220 and the STI feature 222. In some implementations, the dielectric layer 226 includes a different dielectric material from a dielectric material of the insulation features 222. In some implementations, the dielectric layer 226 is SiON and is formed using plasma enhanced atomic layer deposition (“PEALD”). In-situ doping procedure is used to insert demanded percentage of nitrogen “N” ions in the SiON material or other low-K dielectric material of the dielectric layer 226. The ion bombardment also increases the density of the SiON material of the dielectric layer 226. Tuning of one or more of the mixed gas ratio among Ar, O2, and N2, different kind of noble gas selected from He, Ne, Ar, or Kr, the process temperature, or the PEALD power helps insertion of demanded percentage of nitrogen ions impurity into the dielectric material and densify the dielectric material. For example, the pulse time may be in a range of: 0.1-3 seconds, inclusive; the treatment time may be in a range of 0.2-2 seconds, inclusive; the pressure may be in a range of 0.5-3 Torr, inclusive; and the power may be in a range of 150-700 W, inclusive. The precursor can be one or more of Bis(diethylamino)silane (BDEAS) [SiH2[N(CH2CH3)2]2 (also referred to as SAM-24), SiH3N (C3H7)2 (also referred to as LTO520), or ris(dimethylamino)silane (also referred to as TDMAS). The demanded percentage of nitrogen ions impurity may be in a range of 2%-15%, inclusive. Resultantly, the SiON material of the dielectric layer 226 includes demanded etch selectivity with respect to silicon oxide or other dielectric materials that are involved in the formation of structures on the fins 220, e.g., dummy or sacrificial gate structure, as described herein. The dielectric layer 226 thus can maintain its integrity after the oxide removal process to remove such silicon oxide or other dielectric materials from the structures formed on the fins 220 so that the integrity of the insulation structure (or STI feature) 222 can be protected by the dielectric layer 226, which reduces leakage from the gate structures formed on the STI 222 and/or from the GAA devices formed on the fins 220, as will be further described herein. As such the dielectric material of the dielectric layer 226 can function as a protection mask layer to prevent STI damage in an oxide removal process.

The dielectric layer 226 can be doped by different mixed gas such as N2, NO₂, NH₃, CF₄, CH₄, Al(CH₄)₃,etc. Further, the in-situ doping can introduce nitrogen ions into various PEALD dielectric materials like SiOₓ, AlOₓ, SiCₓ, SiOₓC_{y}N_{(1-x-y)}, SiNₓ, SiON, or other low-k dielectric materials. The content and quality of the PEALD dielectric in nanosheet structure also can be tuned with operation temperature, plasma power, and different noble gas for plasma dissociation.

While the present discussion uses a replacement gate process as a descriptive example, whereby a sacrificial gate structure is formed and subsequently replaced by a metal gate structure, other configurations are also possible and included in the scope of the disclosure. For example, the dielectric layer 226 of SiON may also be used to protect the STI feature 222 so that leakage can be reduced from devices of other types of gate structures formed on the semiconductor fins 220 and the STI feature 222.

In some implementations, the thickness of the dielectric layer 226 is in a range from about 1 nm to about 5 nm.

In FIG. 2F, the cross-sectional view A-A shows the structure 200 from the cross-sectional line A-A as shown in the perspective view. In the description herein, a cross-sectional view of the structure 200, if not specifically identified otherwise, will always be a view from the cross-sectional line A-A, for descriptive and illustrative purposes.

In operation 112, with reference also to FIG. 2G, sacrificial gate structures 224 are formed over the fins 220 and over the insulation structures 222. In some implementations, a sacrificial gate structure 224 is formed over a portion of the fins 220 which is configured to be a channel region. Thus, the sacrificial gate structure 224 is adjacent to the channel region. One or more sacrificial (or dummy) gate structures 224 are also formed over the STI feature 222 for various reasons, e.g., for the ease of fabrication process. The dielectric layer 226 is between the sacrificial gate structures 224 and the fins 220 and between the sacrificial gate structures 224 and the STI structures 222. The sacrificial gate structure 224 may be formed using various approaches, which are all included in the scope of the disclosure. For example, a sacrificial gate electrode layer 228 is deposited on the dielectric layer 226 and over the fins 220 or the STI structure 222. The fins 220 are fully embedded in the sacrificial gate electrode layer 228. The sacrificial gate electrode layer 228 includes silicon such as polycrystalline silicon or amorphous silicon. The thickness of the sacrificial gate electrode layer 228 is in a range from about 100 nm to about 200 nm in some implementations. In some implementations, the sacrificial gate electrode layer 228 is subjected to a planarization operation. The sacrificial gate electrode layer 228 are deposited using CVD, including LPCVD and PECVD, PVD, ALD, or other suitable process. Subsequently, a mask layer 230 is formed over the sacrificial gate electrode layer 228. In some implementations, the mask layer 230 includes a pad SiN layer 230A and a silicon oxide mask layer 230B. Next, a patterning operation is performed on the mask layer 230 and the sacrificial gate electrode layer 228 such that the sacrificial gate electrode layer 228 is patterned into sacrificial gate electrode 228 (same reference numeral 228 is used to refer to the sacrificial gate electrode layer and the sacrificial gate electrode for simplicity), as shown in FIG. 2G. The sacrificial gate electrode structure 224 includes the sacrificial gate electrode 228 (e.g., poly silicon), the pad SiN layer 230A, and the silicon oxide mask layer 230B.

In operation 114, with reference still to FIG. 2G, after the patterning and formation of the sacrificial gate structure 224, the semiconductor structure 200 is cleaned to remove contaminant or native oxide layers, e.g., through plasma etching using Hydrogen or Hydrogen fluoride “HF”. With the etch selectivity between silicon oxide and the nitrogen containing dielectric material of the dielectric layer 226, e.g., SiON, with respect to HF plasma, the dielectric layer 226 substantially maintains its integrity and remains covering the STI feature 222 and the fins 220 after the oxide cleaning procedure. The selectivity between the nitrogen containing dielectric material of the dielectric layer 226, e.g., SiON, and SiO2 with respect to HF can be further improved by adding acids or alcohols to the HF solutions in the oxide cleaning procedure. For example, ammonium fluoride NH4F (BOE) or its solution can be added into the HF solutions to increase the selectivity between SiON and SiO₂, with SiO₂ being etched out much faster than SiON.

In some implementations, the stacked epitaxial layers 214 and 216 remain being covered by the dielectric layer 226 on opposite sides of the sacrificial gate structure 224, which can be configured to be source/drain (S/D) regions. In this disclosure, as an example, a source region and a drain region can be interchangeably used and the structures thereof are substantially the same and are referred to as a source or drain feature or structure. The number of the sacrificial gate structures 224 is not limited to one, two, or more sacrificial gate structures, which are arranged in the X direction in some implementations. For example, the to-be-formed GAA transistors in each of the NFET region 204 and PFET region 206 may have separated sacrificial gate structures.

In some implementations, the dielectric layer 226 is SiON configured to have etch selectivity with respect to silicon oxide SiO₂. In some implementations, different dielectric materials can be selected for the dielectric layer 226 in a case that different contaminant residuals are involved and are cleaned in a cleaning procedure. The selection of the dielectric material of the layer 226 can be based on, among others, its etch selectivity over the contaminant dielectric residuals involved in the formation of the sacrificial gate structures 224 over the fins 220 or the STI feature 222.

In operation 116, with reference also to FIG. 2H, gate spacers 232 are formed on or adjacent to sidewalls of the sacrificial gate structure 224. The gate spacers 232 may include a dielectric material such as silicon oxide, silicon nitride, silicon carbide, silicon oxynitride, SiCN films, silicon oxycarbide, SiOCN films, and/or combinations thereof. In some implementations, the gate spacers 232 include multiple layers, such as main spacer walls, liner layers, and the like. By way of example, the gate spacers 232 may be formed by blanket depositing a dielectric material layer in a conformal manner over the sacrificial gate structure 224 using processes such as, a CVD process, a subatmospheric CVD (SACVD) process, a flowable CVD process, an ALD process, a PVD process, or other suitable process. In some implementations, the deposition of the dielectric material layer is followed by an etching-back process, e.g., anisotropically, to remove the dielectric material layer from horizontal surfaces and from top surface of the sacrificial gate structure 224 and from over the top surface of the fins 220 adjacent to but not covered by the sacrificial gate structure 224 (e.g., S/D regions). The dielectric material layer of the gate spacers 232 may remain on the sidewalls of the sacrificial gate structure 224 as gate spacers 232 and/or on the sidewalls of the fins 220 as fin spacers (not specifically shown for simplicity). In some implementations, the etching-back process may include a wet etch process, a dry etch process, a multiple-step etch process, and/or a combination thereof. The gate spacers 232 may have a thickness ranging from about 5 nm to about 20 nm.

In some implementations, the dielectric layer 226 is vertically, e.g., in the z-axis, between the gate spacers 232 and the fins 220, and vertically between the gate spacers 232 and the STI feature 222, and overlaps the gate spacers 232.

In operation 118, still with reference to FIG. 2H, portions of the fins 220 are recessed to form source or drain (“S/D”) trenches 234 (also referred to as S/D recesses 234) in the S/D regions, as shown in FIGS. 11A and 11B. The stacked epitaxial layers 214 and 216 are etched down at the S/D regions. In some implementations, operation 118 forms the S/D recesses 234 by a suitable etching process, such as a dry etching process, a wet etching process, or an RIE process. The etching process in operation 118 may implement a global vertical dry etching process using an etchant including a bromine-containing gas, e.g., HBr and/or CHBR₃, a fluorine-containing gas, e.g., CF₄, SF₆, CH₂F₂, CHF₃, and/or C₂F₆, other suitable gases, or combinations thereof. The global vertical etching process removes portions the dielectric layer 226 in the S/D trenches 234.

In some implementations, the global vertical etching uses an etchant NF₃/H₂, with a power in a range of 150-1200W, and a pressure in a range of 1.5-300 mtorr for a dielectric layer and a pressure in a range of 1.5-100 mtorr for an Si layer. The global vertical etching uses an etchant CH₄/N₂, with a power in a range of 150-1200 W, and a pressure in a range of 1.5-100 mtorr for an SiGe layer.

In operation 120, still with reference to FIGS. 2H-2J, interposer structures are formed with cavities at end of the interposer structures. For example, end portions of the sacrificial epitaxial layers 214 of SiGe are laterally etched, to form cavities 238. The amount of the etching of the epitaxial layers 214 is in a range from about 1 nm to about 4 nm in some implementations. The epitaxial layers 214 can be selectively etched by using a wet etchant such as, but not limited to, ammonium hydroxide (NH4OH), tetramethylammonium hydroxide (TMAH), ethylenediamine pyrocatechol (EDP), or potassium hydroxide (KOH) solutions. Alternatively or additionally, lateral ends of the epitaxial layers 214 that are exposed in the S/D recesses 234 may be first selectively oxidized to increase the etch selectivity between the epitaxial layers 214 and 216. In some examples, the oxidation process may be performed by exposing the device 200 to a wet oxidation process, a dry oxidation process, or a combination thereof.

After the cavities 238 are formed, the recessed portions of the epitaxial layers 214 are also referred to as interposer structures 214.

In some implementations, the operation 120 may include forming the interposer structures using dielectric materials or other materials different from epitaxial layer 214. For example, the other materials may be one or more of metal oxide or low-k dielectric like SiOₓ, SiOCNₓ, SiONₓ, SiOCₓ, SiCₓ, etc. For example, as shown in FIG. 2I, the lateral etching may completed remove the epitaxial layers 214 of SiGe to release the gap 239 between epitaxial layers 216 of Si.

As shown in FIG. 2J, the gaps 239 will be refilled with a dielectric material 241, e.g., silicon oxide, and the dielectric material is laterally etched to form the cavities 238. As such, the interposer structures 241 of dielectric materials are formed between epitaxial layers 216 of silicon in the fins 220.

Referring back to FIG. 1, in operation 122, with reference also to FIG. 2K, inner spacers 240 are formed adjacent to SiGe interposer structures 214 (or dielectric interposer structures 241) and vertically between epitaxial layers 216 of Si. Various approaches may be adopted to form the inner spacers 240. For example, an insulating dielectric layer 240 may be blanketly deposited in the SD recesses 234. Particularly, the insulating dielectric layer 240 is deposited on the lateral ends of the epitaxial layers 214, which fills in the cavities 238, and on the sidewalls of the epitaxial layers 216 exposed in the S/D recesses 234. The insulating dielectric layer 240 may also cover the gate spacers 232, the fin-shape base 220B, and the STI feature 222. The insulating dielectric layer 240 may include silicon oxides, silicon nitrides, silicon carbides, silicon carbide nitride, silicon oxide carbide, silicon carbide oxynitride, and/or other suitable dielectric materials. In some implementations, the insulating dielectric layer 240 is deposited as a conformal layer with substantially uniform thickness on different surfaces. The insulating dielectric layer 240 can be formed by ALD or any other suitable method. By conformally forming the insulating dielectric layer 240, a volume of each of the cavities 238 is reduced or the cavities 238 are completely filled.

The insulating dielectric layer 240 is then partially removed from the S/D recesses 234 through an etching process. By this etching, the insulating dielectric layer 240 remains substantially within the cavity 238, because of the relatively small volume of the cavities 238. Generally, plasma dry etching etches a layer in wide and flat areas faster than a layer in concave (e.g., holes, grooves and/or slits) portions. Thus, the insulating dielectric layer 240 can remain inside the cavities 238. The remained portions of the insulating dielectric layer 240 inside the cavities 238 become inner spacers 240 that provide isolation between to-be-formed metal gate structure and to-be-formed source or drain features.

The dielectric layer 226 is positioned above inner spacers 240 with respect to the substrate 202.

In operation 124, still with reference to FIG. 2K, epitaxial source or drain features 250 are formed in the S/D recesses 234. In some implementations, the forming the epitaxial source or drain features 250 includes epitaxially growing one or more semiconductor layers by a molecular-beam epitaxy MBE process, a chemical vapor deposition process, and/or other suitable epitaxial growth processes. In some implementations, the epitaxial S/D features 250 are in-situ or ex-situ doped with an n-type dopant or a p-type dopant. For example, in some implementations, the epitaxial source or drain features 250 include silicon doped with phosphorous for forming source or drain features for an n-type FET in the NFET region 204. In some implementations, the epitaxial source or drain features 250 include silicon-germanium (SiGe) doped with boron for forming source or drain features for a p-type FET in the PFET region 206. In the illustrated examples, the operation 124 grows epitaxial source or drain features 250 in the NFET region 204. The semiconductor layers of the epitaxial source or drain features 250 are selectively grown on different semiconductor surfaces exposed in the S/D recesses 234, such as the lateral ends of the epitaxial layers 216 of silicon and the small exposed top surface 252 of the fin-shape base 220B (if not completely covered by the insulating dielectric layer 240).

The dielectric layer 226 is positioned between the epitaxial source or drain features 250 and the sacrificial gate structures 224. The epitaxial source or drain feature 250 is in contact with the dielectric layer 226 laterally.

In some implementations, referring to FIG. 2L, an interlayer dielectric (ILD) layer 252 is formed over the epitaxial S/D features 250 and/or laterally adjacent to the sacrificial gate structures 224, or specifically adjacent to the gate spacers 232. A contact etch stop layer (CESL) (not shown) may also be formed under the ILD layer 252, in accordance with some implementations. The CESL layer may include silicon nitride, silicon oxynitride, silicon nitride with oxygen (O) or carbon (C) elements, and/or other materials; and may be formed by CVD, PVD (physical vapor deposition), ALD, or other suitable methods. The ILD layer 252 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 252 may be formed by PECVD or FCVD (flowable CVD), or other suitable methods. In some implementations, forming the ILD layer 252 further includes performing a CMP process to planarize a top surface of the device 200, such that the top surfaces of the sacrificial gate structures 224 are exposed from the gate spacers 232. In some implementations, an etch stop layer or hard mask layer 254 is formed on top of the ILD layer 252.

In operation 126, still with reference to FIG. 2L, the sacrificial gate structures 224 are removed to form a gate trench 260 in the fins 220 and a dummy gate trench 261 over the STI 222. The gate trench 260 exposes the epitaxial layers 216 and the interposer 214 (or dielectric interposer 241) in the channel region. The ILD layer 252 (and the CESL layer) and the dielectric layer 226 protect the epitaxial S/D features 250 during the removal of the sacrificial gate structure 224. The sacrificial gate structure 224 can be removed using plasma dry etching and/or wet etching. When the sacrificial gate electrode layer is polysilicon and the ILD layer 252 is silicon oxide, a wet etchant such as a TMAH solution can be used to selectively remove the sacrificial gate electrode layer.

In some implementations, the dielectric layer 226 is removed in the gate trench 260 using plasma dry etching and/or wet etching, although the dielectric layer 226 remains under the gate spacer 232 and remains covering the STI feature 222.

In some implementations, the dielectric layer 226 is not removed and remains covering the STI 222 under the dummy gate trench 261.

In operation 128, still with reference to FIG. 2L, channel structures are released from the channel region of the GAA device. In the illustrative example, for n-type devices, the channel structures are the epitaxial layers 216 of Si in the form of nanosheets or nanotubes. The plurality of epitaxial layers 214 (or the dielectric interposers 241), now in the form of interposers, may be selectively removed. In some implementations, the selectively removal process includes oxidizing the plurality of epitaxial layers 214 using a suitable oxidizer, such as ozone. Thereafter, the oxidized epitaxial layers 214 may be selectively removed from the gate trench 260. For a p-type GAA device that uses epitaxial layers 214 of SiGe as the channels, the epitaxial layers 214 of Si will be selectively removed through a dry etching process, for example, by applying an HCl gas at a temperature of about 500° C. to about 700° C., or applying a gas mixture of CF4, SF6, and CHF3. For the sake of simplicity and clarity, after operation 128, the epitaxial layers 216 of Si are denoted as channel structures 216. At this point, vertically stacked channel structures 216 are formed in the channel regions of the n-type GAA device in the NFET region 204.

The dielectric layer 226 is vertically between the gate spacer 232 and the channel structures 216. As shown in FIG. 2L-1, in a top view, e.g., from cutting line 1-1 shown in FIG. 2L, it is shown that in some implementations, the dielectric layer 226 is also laterally between the gate spacer 232 and the inner spacer 240.

At operation 130, with reference also to FIG. 2M, metal gate structures 262 are formed in the gate trench 260 wrapping each of the channel structures 216 in the channel region, and dummy metal gates structures 263 are formed in the dummy gate trenches 261. The metal gate structure 268 also engages the top surface of the fin-shape base 220B. The inner spacers 240 separate the metal gate structure 262 from contacting the epitaxial source or drain features 250. Further, the dielectric layer 226 is under the gate spacers 232 and is between the metal gate structure 260 and the source or drain feature 250, and separate the metal gate structure 260 from the source or drain feature 250.

The metal gate structure 262 each includes a gate dielectric layer (not specifically shown) wrapping each channel structures 216 in the channel region and a gate electrode layer formed on the gate dielectric layer. In some implementations, the gate dielectric layer includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO2-Al2O3) alloy, other suitable high-k dielectric materials, and/or combinations thereof. In some implementations, the gate dielectric layer includes an interfacial layer formed between the channel structures and the dielectric material. The gate dielectric layer may be formed by CVD, ALD or any suitable method. In one implementation, the gate dielectric layer is formed using a highly conformal deposition process such as ALD in order to ensure the formation of a gate dielectric layer having a uniform thickness around each channel layers. The gate electrode layer is formed on the gate dielectric layer to surround each channel structure. The gate electrode layer includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer may be formed by CVD, ALD, electro-plating, or other suitable method. In some implementations, one or more work function adjustment layers are interposed between the gate dielectric layer and the gate electrode layer. The work function adjustment layers are made of a conductive material such as a single layer of TiN, TaN, TaAlC, TiC, TaC, Co, Al, TiAl, HfTi, TiSi, TaSi or TiAlC, or a multilayer of two or more of these materials. For the n-channel FET, one or more of TaN, TaAlC, TiN, TiC, Co, TiAl, HfTi, TiSi and TaSi is used as the work function adjustment layer, and for the p-channel FET, one or more of TiAlC, Al, TiAl, TaN, TaAlC, TiN, TiC and Co is used as the work function adjustment layer. The work function adjustment layer may be formed by ALD, PVD, CVD, e-beam evaporation, or other suitable process. Further, the work function adjustment layer may be formed separately for the n-channel FET and the p-channel FET which may use different metal layers.

The gate dielectric is between the dielectric layer 226 and the metal gate electrode.

The dummy gate structures 263 include similar gate dielectrics and gate electrodes as the metal gate structure 262, although the dummy gate structure are formed over the STI feature 222. The dielectric layer 226 is positioned between the dummy gate structures 263 and the STI feature 222. The dielectric layer 226 covers a portion of the insulation feature that is offset from the second gate spacer and the dummy gate structure

As shown in FIG. 2M, a GAA device 300 includes a gate structure 262 that wraps around or adjacent to a plurality of nano-sheet or nano-tube channel structures 216. The source or drain feature 250 is in contact with the plurality of channel structures 216. The inner spacers 240 are positioned between the gate structure 262 and the source or drain feature 250. The gate spacers 232 (also referred to as outer spacers) are positioned between the gate structure 262 and the ILD layer 252. The gate structure includes gate dielectric and metal gate electrode on the gate dielectric. In some implementations, the dielectric layer 226 remains under the gate spacer 232 and between the gate structure 262 (including the gate dielectric and the metal gate electrode) and the source or drain feature 250. The existence of the dielectric layer 226 can reduce electrical leakage of the GAA device 300.

Further the structure 200 also includes dummy gate structures 263 on the STI feature(s) 222. The gate spacers 232 are positioned adjacent to the dummy gate structures 263 and are surrounded by ILD layer 252. The dielectric layer 226 remain integrity between the dummy gate structures 263 and the STI feature 222 and also areas 265 of the STI features 222 that is offset from and laterally adjacent to the dummy gate structures 263 and the corresponding gate spacers 232. The etch selectivity of the SiON material of the dielectric layer 226 enables the dielectric layer 226 to maintain its integrity through the various oxide etching or oxide cleaning procedures involved in the formation of structures or features on the STI feature 222 or the fins 220.

In some implementations, as shown in FIG. 2M-1, the dielectric layer 226 is patterned before or after the formation of the sacrificial gate structure 224 so that the dielectric layer 226 is not present between the dummy gate structure 263 and the STI feature 222. In some implementations, as shown in FIG. 2M-1, the dielectric layer 226 is patterned to be present laterally between dummy gate structures 263. In some implementations, the dielectric layer 226 may be patterned to be not present over the STI feature 222.

In some implementations, a method of manufacturing a semiconductor device includes: forming a fin structure over a substrate, the fin structure including first semiconductor layers and second semiconductor layers alternately stacked; forming a dielectric layer over the fin structure, the dielectric layer including a dielectric material having etch selectivity over silicon oxide; forming a first sacrificial gate structure over the fin structure; forming a first gate spacer adjacent to the first sacrificial gate structure, the dielectric layer below and at least partially overlapping the first gate spacer; removing the first sacrificial gate structure to form a first gate trench; and forming a metal gate structure in the first gate trench, the first gate spacer adjacent to the metal gate structure, and the dielectric layer remaining below and at least partially overlapping the first gate spacer.

In some implementations, a method of manufacturing a semiconductor device includes: forming a fin structure over a substrate, the fin structure including first semiconductor layers and second semiconductor layers alternately stacked; forming an insulation feature over the substrate and laterally with respect to the fin structure; forming a first dielectric layer over the insulation feature and over the fin structure; forming a first sacrificial gate structure over the insulation feature, the first dielectric layer between the first sacrificial gate structure and the insulation feature; forming a second dielectric layer laterally adjacent to the first sacrificial gate structure; removing the first sacrificial gate structure to form a dummy gate trench; and forming a dummy gate structure in the dummy gate trench, the first dielectric layer between the dummy gate structure and the insulation feature.

In some implementations, a semiconductor structure includes: channel structures disposed over a substrate; a gate structure engaging the channel structures; a source or drain feature in contact with the channel structures; an inner spacer interposing the gate structure and the source or drain feature; and a dielectric layer interposing the gate structure and the source or drain feature, the dielectric layer positioned above the inner spacer, and the dielectric layer being a different layer from the inner spacer.

The foregoing outlines features of several implementations so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the implementations introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a fin structure over a substrate, the fin structure including first semiconductor layers and second semiconductor layers alternately stacked;
forming a dielectric layer over the fin structure, the dielectric layer including a dielectric material having etch selectivity over silicon oxide;
forming a first sacrificial gate structure over the fin structure;
forming a first gate spacer adjacent to the first sacrificial gate structure, the dielectric layer below and at least partially overlapping the first gate spacer;
removing the first sacrificial gate structure to form a first gate trench; and
forming a metal gate structure in the first gate trench, the first gate spacer adjacent to the metal gate structure, and the dielectric layer remaining below and at least partially overlapping the first gate spacer.

2. The method of claim 1, comprising:
forming an insulation feature over the substrate and laterally with respect to the fin structure;
forming the dielectric layer over the insulation feature;
forming a second sacrificial gate structure over the insulation feature, the dielectric layer between the second sacrificial gate structure and the insulation feature;
forming a second gate spacer adjacent to the second sacrificial gate structure;
removing the second sacrificial gate structure to form a dummy gate trench; and
forming a dummy gate structure in the dummy gate trench, the dielectric layer between the dummy gate structure and the insulation feature.

3. The method of claim 2, wherein the dielectric layer separates the dummy gate structure from the insulation feature.

4. The method of claim 2, wherein the dielectric layer is between the second gate spacer and the insulation feature.

5. The method of claim 2, wherein the dielectric layer covers a portion of the insulation feature that is offset from the second gate spacer and the dummy gate structure.

6. The method of claim 1, wherein the dielectric layer is SiON.

7. The method of claim 1, wherein the forming the dielectric layer includes performing in-situ doping of nitrogen ions into a low-k dielectric material of the dielectric layer.

8. The method of claim 6, wherein the dielectric layer is formed through plasma enhanced atomic layer deposition using a gas mixture including nitrogen ions and a noble gas selected from one or more of He, Ne, Ar, or Kr.

9. A method of manufacturing a semiconductor device, comprising:
forming a fin structure over a substrate, the fin structure including first semiconductor layers and second semiconductor layers alternately stacked;
forming an insulation feature over the substrate and laterally with respect to the fin structure;
forming a first dielectric layer over the insulation feature and over the fin structure;
forming a first sacrificial gate structure over the insulation feature, the first dielectric layer between the first sacrificial gate structure and the insulation feature;
forming a second dielectric layer laterally adjacent to the first sacrificial gate structure;
removing the first sacrificial gate structure to form a dummy gate trench; and
forming a dummy gate structure in the dummy gate trench, the first dielectric layer between the dummy gate structure and the insulation feature.

10. The method of claim 9, wherein the first dielectric layer separates the dummy gate structure from the insulation feature.

11. The method of claim 9, wherein the dielectric layer is between the second dielectric layer and the insulation feature.

12. The method of claim 9, comprising:
forming a second sacrificial gate structure over the fin structure, the first dielectric layer between the second sacrificial gate structure and the fin structure;
forming a source or drain recess by etching a source or drain region of the fin structure, which is not covered by the second sacrificial gate structure;
growing an epitaxial source or drain feature in the source or drain recess, the epitaxial source or drain feature in contact with the first dielectric layer laterally.

13. The method of claim 12, comprising:
removing the second sacrificial gate structure to form a gate trench; and
forming a metal gate structure in the gate trench, the first dielectric layer between the metal gate structure and the epitaxial source or drain feature.

14. The method of claim 13, wherein the metal gate structure include a gate dielectric and a metal gate electrode, and the gate dielectric is between the first dielectric layer and the metal gate electrode.

15. The method of claim 9, wherein the first dielectric layer includes a different dielectric material from a dielectric material of the insulation feature.

16. The method of claim 12, comprising:
laterally recessing the first semiconductor layers through the source or drain recess, thereby forming cavities; and
depositing a third dielectric layer in the cavities.

17. The method of claim 13, comprising:
removing the first semiconductor layers from a channel region of the fin structure,
wherein the forming the metal gate structure includes forming the metal gate structure that wraps around each of the second semiconductor layers in the channel region.

18. A semiconductor structure, comprising:
channel structures disposed over a substrate;
a gate structure engaging the channel structures;
a source or drain feature in contact with the channel structures;
an inner spacer interposing the gate structure and the source or drain feature; and
a dielectric layer interposing the gate structure and the source or drain feature, the dielectric layer positioned above the inner spacer, and the dielectric layer being a different layer from the inner spacer.

19. The semiconductor device of claim 18, comprising:
an insulation feature disposed laterally with respect to the channel structures; and
a dummy gate structure over the insulation feature,
wherein the dielectric layer is between the dummy gate structure and the insulation feature.

20. The semiconductor device of claim 18, comprising:
a gate spacer laterally adjacent to the gate structure,
wherein the dielectric layer is between the gate spacer and the channel structures.
